(19) United States
(12) Patent Application Publication
(10) Pub. No.: US 2022/0058992 A1
(43) Pub. Date: Feb. 24, 2022

(54) ROTARY SCREEN DEVICE AND METHOD FOR CONTROLLING THE ROTARY SCREEN DEVICE

(71) Applicant: Wireless-Tag Technology Co., Limited, Shenzhen (CN)

(72) Inventors: Zhougang WEN, Shenzhen (CN); Yunxiang MU, Shenzhen (CN); Hui LI, Shenzhen (CN); Honggang WANG, Shenzhen (CN)

(21) Appl. No.: 17/516,919

(22) Filed: Nov. 2, 2021

Related U.S. Application Data
(63) Continuation of application No. PCT/CN2021/077553, filed on Feb. 24, 2021.

(30) Foreign Application Priority Data
Oct. 19, 2020 (CN) 202011115707.9

(51) Int. Cl. G09F 9/30; G05G 1/10; H03K 17/90

(52) U.S. Cl. CPC G09F 9/301; H03K 17/90; G05G 1/10

(57) ABSTRACT

The present disclosure relates to the technical field of rotary screen, and provides a rotary screen device and a method for controlling the rotary screen device. The rotary screen device includes a transparent window, a display panel, a panel support frame, a rotating housing, a main board, and a base, the main board is provided with a Hall sensor, a magnet, and a roller. The rotary screen device of the present disclosure is compact, easy to operate, and responsive.

### CROSS-REFERENCE TO RELATED APPLICATIONS

This application is a continuation of International Application No. PCT/CN2021/077553, filed on Oct. 19, 2020, which claims the benefit of priority from Chinese Patent Application No. 202011115707.9, filed on Oct. 19, 2020. The content of the aforementioned applications, including any intervening amendments thereto, are incorporated herein by reference.

### FIELD

The present disclosure relates to the technical field of rotary screen, in particular to a rotary screen device and a method for controlling the rotary screen device.

### BACKGROUND

With the rapid development of the electrical industry, the rotary screens are widely used in products, such as washing machines, microwave ovens, etc.

Consumers are increasingly demanding operating experience. However, the existing rotary devices have disadvantages such as complex structure, larger volume, and poor sensitivity, etc.

Therefore, the existing rotary screen devices should be improved.

### SUMMARY

In view of the above problems, the present disclosure provides a rotary screen device and a method for controlling the rotary screen device, aiming to make the rotary screen device compact, easy to operate, and responsive.

In order to solve the above problems, the present disclosure provides a rotary screen device, including a transparent window, a display panel, a panel support frame, a rotating housing, a main board, and a base. The main board is provided with a Hall sensor, a magnet, and a roller

An inner side of the rotating housing is provided with a track matched with the roller.

The Hall sensor and the magnet are respectively arranged on two sides of the main board.

The roller is coaxially connected with the magnet, and configured to drive the magnet to rotate.

A relative position of the Hall sensor and the magnet remains unchanged.

The base defines an opening matched with the roller.

The roller is elastic and higher than a plane of the main board.

The rotary screen device is provided with a voice control module.

The smaller the roller, the more the magnet rotates when the roller rotates at the same angle, the more pulse signals the system distinguishes.

The present disclosure further provides a method for controlling the rotary screen device.

The method for controlling the rotary screen device includes: rotating a rotating housing to drive a roller to move; driving the magnet to rotate by a movement of the roller; sensing by the Hall sensor a rotation of the magnet; judging rotating data according to a pulse signal sent by the Hall sensor; and performing corresponding procedures.

The rotary screen device also supports a voice control.

The beneficial effects of the present disclosure include: different from the existing art, the present disclosure provides the rotary screen device and the method for controlling the rotary screen device, the rotary screen device includes the transparent window, the display panel, the panel support frame, the rotating housing, the main board and the base, the main board is provided with the Hall sensor, the magnet and the roller. In this way, the rotary screen device can be exquisite in structure, easy to operate, and responsive.

### BRIEF DESCRIPTION OF THE DRAWINGS

To illustrate the technical solutions according to the embodiments of the present disclosure or in the prior art more clearly, the accompanying drawings for describing the embodiments or the prior art are introduced briefly in the following. Apparently, the accompanying drawings in the following description are only about some embodiments of the present disclosure, and persons of ordinary skill in the art can derive other drawings from the accompanying drawings without creative efforts.

FIG. 1 is an exploded view of a rotary screen device of the present disclosure;

FIG. 2 is an enlarged view of a part of the rotary screen device of the present disclosure;

FIG. 3 is a perspective view of the rotary screen device of the present disclosure;

FIG. 4 is a flowchart of a method for controlling the rotary screen device of the present disclosure.

### LABELS ILLUSTRATION FOR DRAWINGS

| Label | Name | Label | Name |
|---|---|---|---|
| 10 | transparent window | 20 | display panel |
| 30 | panel support frame | 40 | rotating housing |
| 50 | main board | 60 | base |
| 70 | voice control module | 410 | track |
| 510 | Hall sensor | 520 | magnet |
| 530 | roller | 610 | opening |

### DETAILED DESCRIPTION OF EMBODIMENTS

The technical solutions of the embodiments of the present disclosure will be clearly and completely described in the following with reference to the accompanying drawings. It is to be understood that the specific embodiments described herein are merely used for describing the present disclosure, but are not intended to limit the present disclosure. In addition, it should be noted that, for ease of description, the drawings only show parts of the structures related to the present disclosure instead of all of the structures. All other embodiments obtained by persons skilled in the art based on the embodiments of the present disclosure without creative efforts shall fall within the protection scope of the present disclosure.

It should be noted that, all the directional indications in the embodiments of the present disclosure, such as up, down, left, right, front, and rear etc., are only used to explain the relative positional relationship and movement between the components in a certain posture. If the specific posture changes, the directional indications change accordingly.

In addition, the descriptions of “first”, “second”, etc., in this present disclosure are used for descriptive purposes only, and are not to be construed as indicating or implying their relative importance or implicitly indicating the number of technical features indicated. Thus, features defining “first” or “second” may include at least one of the features, either explicitly or implicitly. In addition, the technical proposal of each exemplary embodiment can be combined with each other, however the technical proposal must base on that the ordinary skill in that art can realize the technical proposal, when the combination of the technical proposals occurs contradiction or cannot realize, it should consider that the combination of the technical proposals does not existed, and is not contained in the protection scope required by the present disclosure.

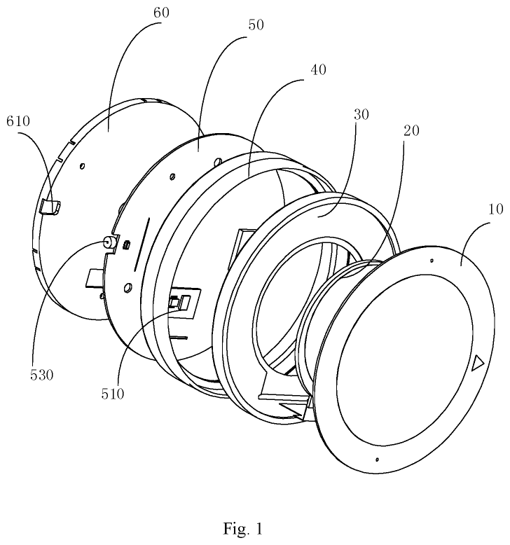

Referring to FIG. 1, which is an exploded view of a rotary screen device of the present disclosure.

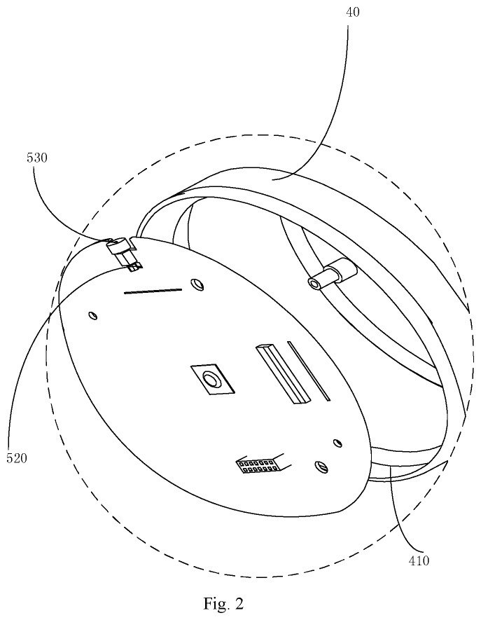

Referring to FIG. 2, which is an enlarged view of a part of the rotary screen device of the present disclosure.

The rotary screen device includes: a transparent window 10, a display panel 20, a panel support frame 30, a rotating housing 40, a main board 50, and a base 60. The main board 50 is provided with a Hall sensor 510, a magnet 520 and a roller 530.

In some embodiments, the display panel 20 is preferably formed by bonding a glass panel or an acrylic panel to a screen.

In some embodiments, the panel support frame 30 is made of a translucent material, and the main board 50 is also provided with background lamp beads. The translucent support frame can realize an edge background lighting effect.

Referring to FIG. 1 and FIG. 2, an inner side of the rotating housing 40 is provided with a track 410 matched with the roller 530.

The Hall sensor 510 and the magnet 520 are respectively arranged on two sides of the main board 50.

It can be understood that the Hall sensor 510 and the magnet 520 are respectively arranged on two sides of the main board 50 to effectively utilize a thickness of the main board 50, thereby reducing a thickness of the rotary screen device.

Further, the magnet 520 and the Hall sensor 510 are located on two different sides of the main board 50, so that the magnet 520, the Hall sensor 510 and the main board 50 only occupy a small space, and the user can get a more detailed rotary experience. The smaller the roller 530 on the right, the more the magnet 520 rotates when the roller 530 rotates at the same angle, the more pulse signals the Hall sensor 510 can distinguish, that is to say, the sensitivity of rotation is correspondingly high.

The roller 530 is coaxially connected with the magnet 520, and the magnet 520 is driven to rotate by the roller 530.

When the magnet 520 rotates, a relative position of the Hall sensor 510 and the magnet 520 remains unchanged.

Further, the base 60 is provided with an opening 610 matched with the roller 530.

It can be understood that the roller 530 is embedded in the opening 610 of the base 60 to make a full use of the space and effectively reduce the overall thickness of the rotary screen device.

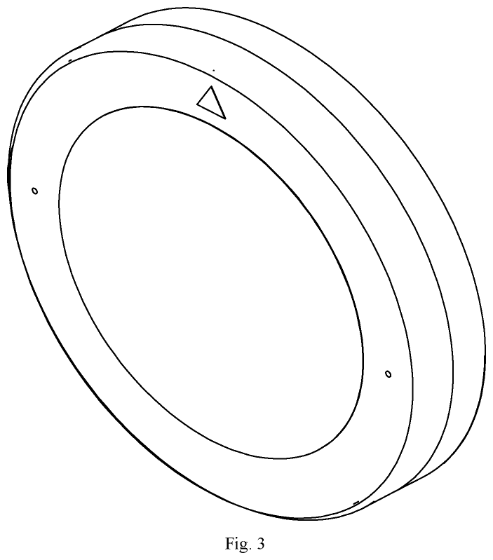

Refer to FIG. 3, which is a perspective view of the rotary screen device of the present disclosure.

It is understandable that the rotary screen device is exquisite, concise, easy to install, and can be applied to a variety of products.

The roller 530 is elastic, and slightly higher than a plane of the main board 50. The roller 530 protrudes from a surface of the main board 50.

It can be understood that the roller 530 contacts a track 410 inside the rotating housing 40. When the rotating housing 40 rotates, the track 410 and the roller 530 generate a relative movement, and the friction may drive the roller 530 to rotate.

In some embodiments, the rotary screen device is further provided with a voice control module 70. The voice control module 70 can execute corresponding programs when receiving a voice instruction, and a UI interface of the display panel 20 may display the corresponding programs. The user has a variety of ways to use the rotary screen device.

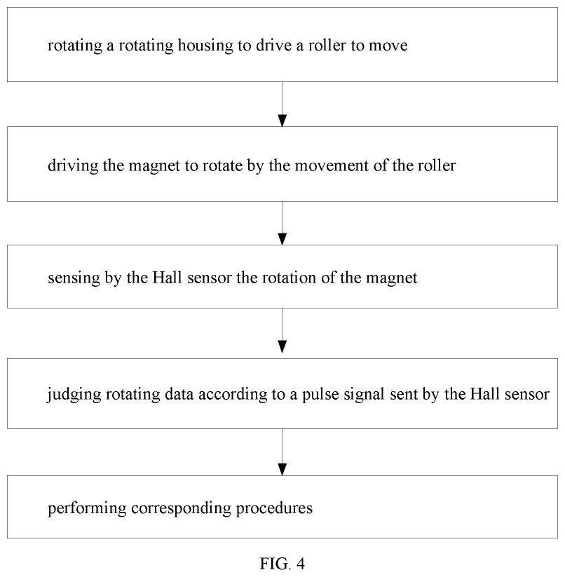

Refer to FIG. 4, which is a flowchart of a method for controlling the rotary screen device of the present disclosure.

In some embodiments, the method includes the following steps:

rotating a rotating housing to drive a roller to move;

driving the magnet to rotate by a movement of the roller;

sensing by the Hall sensor a rotation of the magnet;

judging rotating data according to a pulse signal sent by the Hall sensor; and

performing corresponding procedures.

Different from the existing art, the rotary screen device of the present disclosure includes: the transparent window, the display panel, the panel support frame, the rotating housing, the main board, and the base, and the Hall sensors, the magnet and the roller are provided on the main board. In this way, the rotary screen device can be exquisite in structure, easy to operate, and responsive.

In the implementation manners provided in the present disclosure, it should be understood that the disclosed methods and structures can be implemented in other ways. For example, the implementation manners of the structures described above are only illustrative, and there may be other implementation manners. For example, multiple units or components may be combined or integrated into another system, or some features may be ignored or not implemented.

The above are only optional embodiments of the present disclosure, and thus do not limit the scope of the present disclosure. Any equivalent structure or equivalent process transformation made by using the description and drawings of the present disclosure is included in the scope of the present disclosure.

What is claimed is:

1. A rotary screen device, comprising a transparent window, a display panel, a panel support frame, a rotating housing, a main board, and a base, wherein, the main board is provided with a Hall sensor, a magnet, and a roller.

2. The rotary screen device of claim 1, wherein, an inner side of the rotating housing is provided with a track matched with the roller.

3. The rotary screen device of claim 1, wherein, the Hall sensor and the magnet are respectively arranged on two sides of the main board.

4. The rotary screen device of claim 2, wherein, the roller is coaxially connected with the magnet, and configured to drive the magnet to rotate.

5. The rotary screen device of claim 3, wherein, a relative position of the Hall sensor and the magnet remains unchanged.

6. The rotary screen device of claim 1, wherein, the base defines an opening matched with the roller.

7. The rotary screen device of claim 1, wherein, the roller is elastic and higher than a plane of the main board.

8. The rotary screen device of claim 7, wherein, the rotary screen device is provided with a voice control module.

9. The rotary screen device of claim 2, wherein, the roller is elastic and higher than a plane of the main board.

10. The rotary screen device of claim 9, wherein, the rotary screen device is provided with a voice control module.

11. The rotary screen device of claim 3, wherein, the roller is elastic and higher than a plane of the main board.

12. The rotary screen device of claim 11, wherein, the rotary screen device is provided with a voice control module.

13. The rotary screen device of claim 4, wherein, the roller is elastic and higher than a plane of the main board.

14. The rotary screen device of claim 13, wherein, the rotary screen device is provided with a voice control module.

15. The rotary screen device of claim 5, wherein, the roller is elastic and higher than a plane of the main board.

16. The rotary screen device of claim 15, wherein, the rotary screen device is provided with a voice control module.

17. The rotary screen device of claim 6, wherein, the roller is elastic and higher than a plane of the main board.

18. The rotary screen device of claim 17, wherein, the rotary screen device is provided with a voice control module.

19. A method for controlling a rotary screen device, comprising:
rotating a rotating housing to drive a roller to move;
driving the magnet to rotate by a movement of the roller;
sensing by the Hall sensor a rotation of the magnet;
judging rotating data according to a pulse signal sent by the Hall sensor; and
performing corresponding procedures.

20. The method for controlling a rotary screen device of claim 19, wherein, the smaller the roller, the more the magnet rotates when the roller rotates at the same angle, the more pulse signals the system distinguishes.
